(19) United States
(12) Patent Application Publication
(10) Pub. No.: US 2025/0112069 A1
(43) Pub. Date: Apr. 3, 2025

(54) PACKAGE TRAYS FOR SEMICONDUCTOR PACKAGES AND RELATED METHODS

(71) Applicant: SEMICONDUCTOR COMPONENTS INDUSTRIES, LLC, Scottsdale, AZ (US)

(72) Inventor: Byounghee LEE, Boise, ID (US)

(73) Assignee: SEMICONDUCTOR COMPONENTS INDUSTRIES, LLC, Scottsdale, AZ (US)

(21) Appl. No.: 18/478,115

(22) Filed: Sep. 29, 2023

(51) Int. Cl. H01L 21/673; H01L 27/146

(52) U.S. Cl. CPC H01L 21/67336; H10F 39/011

(57) ABSTRACT

Implementations of a package tray may include a base and a grid of electromagnetic radiation reflectors coupled to a largest planar side of the base; wherein sidewalls of the grid of electromagnetic radiation reflectors may be configured to direct electromagnetic radiation toward sides of a plurality of semiconductor packages located within the grid. The electromagnetic radiation may be configured to assist in curing a component of the plurality of semiconductor packages.

### BACKGROUND

### 1. Technical Field

Aspects of this document relate generally to semiconductor devices. More specific implementations involve image sensor devices.

### 2. Background

Semiconductor packages have been devised for various semiconductor devices. Semiconductor packages contain structures that route electrical signals from semiconductor die to a motherboard or circuit board to which the semiconductor packages are attached. Other semiconductor packages contain structures used to protect the semiconductor die from electrostatic discharge, humidity, or shock and vibration forces.

### SUMMARY

Implementations of a package tray may include a base and a grid of electromagnetic radiation reflectors coupled to a largest planar side of the base; wherein sidewalls of the grid of electromagnetic radiation reflectors may be configured to direct electromagnetic radiation toward sides of a plurality of semiconductor packages located within the grid. The electromagnetic radiation may be configured to assist in curing a component of the plurality of semiconductor packages.

Implementations of a package tray may include one, all, or any of the following:

The electromagnetic radiation may be ultraviolet light.

The electromagnetic radiation may be emitted by an electromagnetic radiation source oriented substantially directly above a largest planar surface of the base.

The sidewalls of the grid include a triangular cross sectional shape or a curved cross sectional shape.

The sidewalls of the grid may be triangular and angles of two vertices of the triangular cross sectional shape adjacent to the base may be substantially 45 degrees.

The sidewalls of the grid may be triangular and where angles of two vertices of the triangular cross sectional shape adjacent to the base may be between 45 degrees to 60 degrees.

The sidewalls of the grid include a closed cross sectional shape that may include at least two line segments angled substantially 45 degrees from a plane formed by a largest planar surface of the base.

The grid may be integral with the base.

Implementations of a package tray may include a base including a largest planar surface including a grid of electromagnetic radiation reflectors coupled thereto; wherein sidewalls of the grid of electromagnetic radiation reflectors may be angled to a plane formed by the largest planar surface of the base.

Implementations of a package tray may include one, all, or any of the following:

The sidewalls direct electromagnetic radiation toward sides of a plurality of semiconductor packages located within the grid.

The electromagnetic radiation may be ultraviolet light.

The electromagnetic radiation may be emitted by an electromagnetic radiation source oriented substantially directly above the largest planar surface of the base.

The sidewalls of the grid include a triangular cross sectional shape.

Implementations of a method of curing a plurality of semiconductor packages included in a package tray include providing a base and a grid of electromagnetic radiation reflectors coupled to a largest planar side of the base; placing a plurality of semiconductor packages into openings in the grid resting against the base; directing electromagnetic radiation toward sides of each the plurality of semiconductor packages located within the grid using sidewalls of the grid of electromagnetic radiation reflectors; and curing a component of the plurality of semiconductor packages using the electromagnetic radiation.

Implementations of a method of curing a plurality of semiconductor packages may include one, all, or any of the following:

The electromagnetic radiation may be ultraviolet light.

The method may further include emitting the electromagnetic radiation from an electromagnetic radiation source oriented substantially directly above a largest planar surface of the base.

The sidewalls of the grid may include a triangular cross sectional shape.

Angles of two vertices of the triangular cross sectional shape adjacent to the base may be substantially 45 degrees.

Angles of two vertices of the triangular cross sectional shape adjacent to the base may be between 45 degrees to 60 degrees.

The sidewalls of the grid include a closed cross sectional shape that may include at least two line segments angled substantially 45 degrees from a plane formed by a largest planar surface of the base.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective partial view of an ultraviolet (UV) light curing apparatus and a package tray;

FIG. 2 is another partial perspective view of a UV light curing apparatus and a package tray;

FIG. 3 is a cross sectional view of an image sensor package prior to overmolding;

FIG. 4 is a top down view of a package tray with a grid of electromagnetic radiation reflectors with a plurality of image sensor packages disposed within the grid;

FIG. 5 is a side cross sectional diagram of a portion of a grid of electromagnetic radiation reflectors and a base of a package tray implementation; and

FIG. 6 is a side cross sectional view of a portion of a grid of electromagnetic radiation reflectors and a base of another package tray implementation.

### DESCRIPTION

This disclosure, its aspects and implementations, are not limited to the specific components, assembly procedures or method elements disclosed herein. Many additional components, assembly procedures and/or method elements known in the art consistent with the intended package tray will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such package trays, and implementing components and methods, consistent with the intended operation and methods.

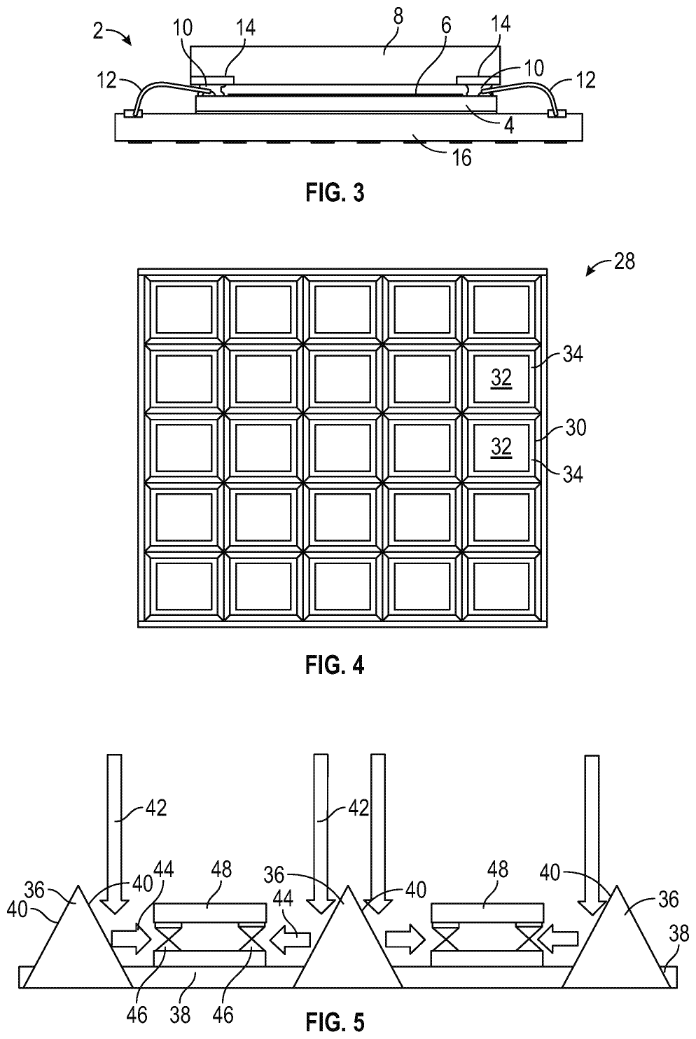

Referring to FIG. 3, a cross sectional view of an implementation of an image sensor package 2 is illustrated. As illustrated, the image sensor package 2 includes an image sensor die 4 that includes a pixel array 6 over which an optically transmissive cover 8 is coupled through glass adhesive/dam material 10. In this package, the bond wires 12 have been formed prior to application of the glass adhesive material 10 so this image sensor package may be referred to as a wire-in-dam package design. Because of the presence of the bond wires 12, the glass adhesive 10, and the bonding pads, additional stray light reflection from the material of the bond wires and bonding pads into the pixel array can cause performance degradation including flare/glare light in the images generated by the pixel array and image sensor package. To help prevent the light reflection or flare/glare light, black mask material 14 is placed under the optically transmissive cover 8 forming a band around the perimeter of the optically transmissive cover 8 which absorbs light transmitted through the optically transmissive cover above the bond wires 12 and pads and prevents it from reaching them. As illustrated in FIG. 3, the image sensor die 4 is bonded to a substrate 16 (in this case a land grid array substrate) which serves to route electrical signals from the image sensor die 4 to the circuit/motherboard to which the image sensor package 2 is ultimately attached. While not illustrated in FIG. 3, in various implementations, a mold compound is disposed around the bond wires, the substrate 16, the glass adhesive 10, and the optically transmissive cover 8 to help seal the edge of the package and provide additional light blocking.

While the black mask 14 works to reduce/eliminate the reflection of stray light (flare/glare light) during operation of the device, it also succeeds in preventing ultraviolet (UV) light from reaching the glass adhesive 10 during a UV curing operation of the glass adhesive 10. Because of this, the curing achieved of the glass adhesive 10 has been observed to be irregular around the perimeter of the image sensor package 2 and irregular among a set of image sensor packages arranged in a package tray during a UV curing operation. The problems created by the uneven curing of the glass adhesive 10 can cause mechanical and chemical failures leading to electrical failures and reliability problems. In some situations, mechanical failures have included delamination and intrusion of the mold compound into the dam area. Chemical failures have included corrosion of the bond wires and/or pads due to migration of ions through the uncured/partially cured glass adhesive material during operation/testing. The corrosion can lead to electrical failures over time as detected by reliability testing.

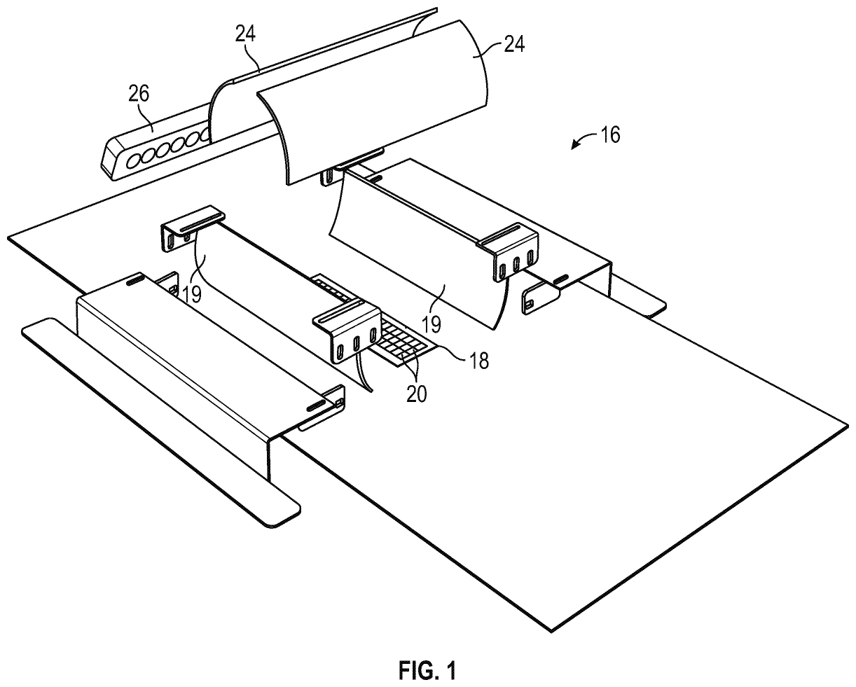

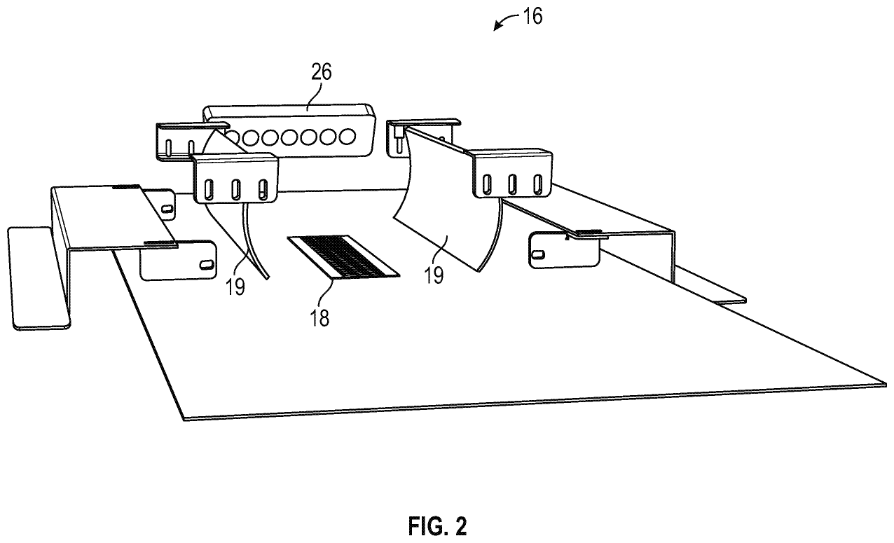

Referring to FIG. 1, a perspective partial view of an implementation of a UV light curing apparatus 16 is illustrated. Only parts of the apparatus are illustrated here to aid in illustration, but those components not shown (light bulb, electrical connectors, housings, etc.) are included in various implementations to aid in the UV curing operation. Package tray 18 is illustrated within the UV light curing apparatus 16 and has a plurality of image sensor packages 20 disposed thereon. As illustrated, central UV light source 22 in the form of a bulb (not shown) emitting diffuse UV light at a desired frequency (ies) is placed between central reflectors 24 which serve to direct the diffusely emitted UV light from the bulb down toward package tray 18. Adjacent to package tray 18 are secondary reflectors 19 that are oriented about 90 degrees from the central reflectors 24 that work to focus the diffusely emitted UV light onto the width of the package tray 18 as it passes through the UV light curing apparatus 16 on a conveyor belt or other transport apparatus (not shown in FIG. 1 for sake of illustration). To aid with generating additional UV light, an array of light emitting diodes 26 that emit UV light is placed at an angle to the package tray to help increase the amount of UV light available to reach under the black mask material and promote the curing reaction in the glass adhesive material. FIG. 2 is a view of the UV light curing apparatus 16 illustrated with the central reflectors removed to show a better angle of the array of light emitting diodes 26 relative to the package tray 18.

The challenge presented by the configuration of the UV light sources and reflectors in the UV light curing apparatus 16 illustrated in FIG. 1 is that the actual illumination experienced by the glass adhesive material present in the sidewall extending around the perimeter of each image sensor package is a factor of the position of each image sensor package in the package tray due to non-uniformities in the illumination provided by the apparatus itself and because of blocking and shading of the glass adhesive material caused by black mask and/or adjacent image sensor packages. Assessing the effects of these nonuniformities is a complex effort as it involves many different variables and the position of each image sensor package within the package tray. Also, because the UV light sources in this system are diffuse light sources as opposed to coherent light sources (like laser light sources), the ability to direct each diffuse ray of UV light to a desired location is limited to a time averaging effect. While every location in the glass adhesive material could theoretically be reached by a ray of diffuse UV light if the package tray remained in the light for an unlimited period of time, this is not practical for high volume image sensor packaging operations.

Referring to FIG. 4, a top-down view of an implementation of a package tray 28 is illustrated that has a grid of electromagnetic radiation reflectors 30 thereon with a plurality of image sensor packages 32 disposed in openings 34 formed by the grid 30. As illustrated, the grid of electromagnetic radiation reflectors 30 surrounds the entire perimeter of each of the image sensor packages 32 and works to direct the diffusely emitted UV light from the UV light curing apparatus 16 and/or the light from the light emitting diodes 26 into/at the edge of each of the image sensor packages 32.

Referring to FIG. 5, a side cross sectional diagram of an implementation of a portion of a grid of electromagnetic radiation reflectors 36 is illustrated coupled to base 38. Here the cross sectional shape of the sidewalls 40 of the grid 36 is triangular—in this case, an equilateral triangle. Arrows 42/44 show the direction of a ray of diffusely emitted UV light from the UV light sources in the apparatus incident substantially vertically on the sidewalls 40 reflected toward the sidewalls and glass adhesive material 46 illustrated for sake of illustration as opposing triangles in FIG. 5. Thus, the use of the grid of electromagnetic radiation reflectors 36 is designed to aid in directing diffusely emitted UV light toward the glass adhesive material all the way around the perimeter of each image sensor package 48. In this way, the use of the grid of electromagnetic radiation reflectors can be used to help combat the effects of shadowing of an image sensor package by another image sensor package. The grid or electromagnetic radiation reflectors can also help direct as much UV light toward the glass adhesive material as possible in a given amount of time. This may decrease the time required to achieve a desired cure of the glass adhesive material 46 and/or may decrease the amount of non-uniformity of the achieved cure of the glass adhesive material 46 around each of the image sensor packages, regardless of their position in the grid of the package tray. In this way, the previously noted mechanical and electrical issues can be minimized or eliminated.

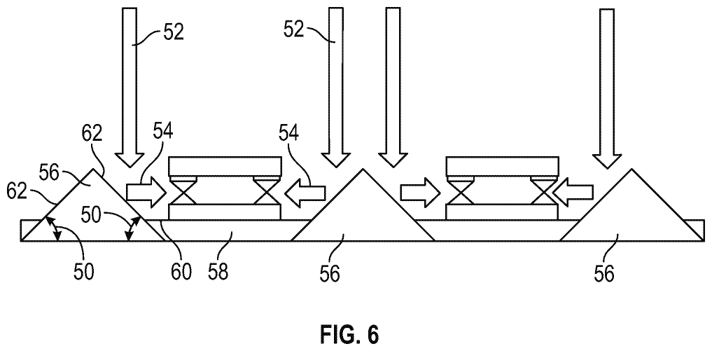

While the angles of the vertices of the triangular cross sectional shape of the grid of electromagnetic radiation reflectors 30 in FIG. 5 is about 60 degrees (that of an equilateral triangle), in other implementations, the angle may be more or less than 60 degrees. Referring to FIG. 6, an implementation is illustrated where the angles 50 of two opposing vertices of the cross sectional shape are about 45 degrees. In this implementation, the arrows 52, 54 indicate that rays of diffuse UV light coming down substantially above the grid of electromagnetic radiation reflectors 56 are directed substantially parallel with the largest planar surface/side 60 of the base 58. In various implementations, the angles of the two vertices of each triangular cross sectional shape may be between about 45 degrees to about 60 degrees. In such implementations, the sidewalls include line segments 62 that are angled at the angle of each of the two vertices, or angles from a plane formed by the largest planar surface 50 of the base 58. In other implementations, the angle of the two vertices may be less than 45 degrees or greater than 60 degrees.

While the implementations illustrated in FIGS. 4-6 utilize sidewalls of the grid of electromagnetic radiation reflectors that have line segments, in other implementations, the sidewalls may be curved in a concave or convex direction, depending on the angles of incidence of the rays of light leaving the diffusely emitting UV light sources. The grid shape and the reflector shape can be customized for best UV illumination conditions on the sensor package sidewalls. In various implementations, the grid shape and/or the sidewalls of the electromagnetic radiation reflectors can be, by non-limiting example, triangular, trapezoidal, circular, polygonal, or any other closed shape. For example, the central reflectors 24 and secondary reflectors 26 are curved at a desired angle to help focus the rays of diffusely emitted UV light at a desired focal point below the reflectors. The use of curved sidewalls would similarly allow for focusing of diffusely emitted incident UV radiation at a desired location/point/area along the sidewalls of the image sensor packages like the glass adhesive material, thus helping to concentrate the curing light into the adhesive material. In this way, issues relating to uneven curing of the glass adhesive material can be minimized or eliminated while the total curing time may be reduced. In various sidewall implementations, the surface of the sidewalls may be angled, curved, or have a structured texture like a light scattering or light diffusing texture in combination with any of the other sidewall angles or shapes disclosed herein.

The material of the grid of electromagnetic radiation reflectors may be made of a wide variety of electromagnetic reflective materials, such as, by non-limiting example, mirror polished aluminum, diffused surface aluminum, aluminum, chrome, mirrored glass, metal, chromed mirrored plastic, chromed ceramics, or any other material capable of reflecting the desired wavelength(s) of electromagnetic radiation. The material of the base may be any of a wide variety of material types including, by non-limiting example, aluminum, steel, brass, plastic, resin or any other material capable of holding a planar shape. In particular implementations, the material of the grid of electromagnetic radiation reflectors may be the same as the material of the base. In such implementations, the grid of electromagnetic radiation reflectors may be integral with the material of the base. Where the grid of electromagnetic radiation reflectors is integral with the base, additional processing of the sidewall surfaces of the grid of electromagnetic radiation reflectors may be carried out, including, by non-limiting example, polishing, electropolishing, mirroring, chroming, electroplating, or electroless plating. After the processing of the sidewalls is completed, the package tray is then ready for use.

The various package tray implementations may be utilized in implementations of a method of curing a plurality of semiconductor packages. The method includes providing a base and a grid of electromagnetic radiation reflectors coupled to a largest planar side of the base. These electromagnetic radiation reflectors may be any type disclosed in this document. The base and the grid of electromagnetic radiation reflectors may be made of any material disclosed in this document as well in various implementations.

The method also includes placing a plurality of semiconductor packages into openings in the grid resting against the base. In various method implementations, this process of placing the plurality of semiconductor packages may take place at the initial step of package formation, where the substrate is initially placed into the openings in the grid and then subsequent packaging operations such as die attach, wirebonding, glass adhesive application, and optically transmissive cover placement then occur as the substrate is resting in the opening in the grid. In these implementations, the package tray acts as the package assembly vehicle. In other method implementations, however, the operations of die attach, wirebonding, glass adhesive, and optically transmissive cover placement may take place at the wafer scale or at the panel scale, and a singulation operation carried out with the glass adhesive in either a partially cured or b-stage cured condition. Following the singulation operation, a pick and place tool or other device may be used to select the singulated packages and place them individually into the openings in the grid of electromagnetic radiation reflectors. In yet other implementations, each image sensor package may be individually formed on an individual substrate through die attach, wirebonding, glass adhesive application, and optically transmissive cover attach operations and then individually place into each opening of the grid of electromagnetic radiation reflectors.

With the plurality of image sensor packages placed into the openings in the grid of electromagnetic radiation reflectors, the method includes directing electromagnetic radiation toward sides/sidewalls of each of the plurality of semiconductor packages using sidewalls of the grid of electromagnetic radiation reflectors. The type of electromagnetic radiation may be any of a wide variety of types including, by non-limiting example, UV, IR, visible light, microwave, x-ray, or any other electromagnetic radiation type. The shape of the sidewalls of the electromagnetic radiation reflectors may be any shape disclosed in this document and they may have any cross sectional shape disclosed herein as well. Also, the various sidewalls may be angled at any set of angles or range of angles disclosed herein as well. The method also include curing a component of the plurality of semiconductor packages using the electromagnetic radiation to initiate a chemical reaction in the component.

In this document, the implementations have disclosed curing a glass adhesive material using UV light. However, in other method and system implementations like those disclosed herein, the material being cured may be different or in addition to the glass adhesive material, including, by non-limiting example, a mold compound, a black mask material, a dam material, a die bonding material, a microlens material, a gapless material between the optically transmissive cover and the pixel array, or any other material type capable of being cured partially or wholly using electromagnetic radiation.

In places where the description above refers to particular implementations of package trays and implementing components, sub-components, methods and sub-methods, it should be readily apparent that a number of modifications may be made without departing from the spirit thereof and that these implementations, implementing components, sub-components, methods and sub-methods may be applied to other package trays.

What is claimed is:

1. A package tray comprising:
a base; and
a grid of electromagnetic radiation reflectors coupled to a largest planar side of the base;
wherein sidewalls of the grid of electromagnetic radiation reflectors are configured to direct electromagnetic radiation toward sides of a plurality of semiconductor packages located within the grid; and
wherein the electromagnetic radiation is configured to assist in curing a component of the plurality of semiconductor packages.

2. The package tray of claim 1, wherein the electromagnetic radiation is ultraviolet light.

3. The package tray of claim 1, wherein the electromagnetic radiation is emitted by an electromagnetic radiation source oriented substantially directly above a largest planar surface of the base.

4. The package tray of claim 1, wherein the sidewalls of the grid comprise a triangular cross sectional shape or a curved cross sectional shape.

5. The package tray of claim 4, wherein the sidewalls of the grid are triangular and angles of two vertices of the triangular cross sectional shape adjacent to the base are substantially 45 degrees.

6. The package tray of claim 4, wherein the sidewalls of the grid are triangular and where angles of two vertices of the triangular cross sectional shape adjacent to the base is between 45 degrees to 60 degrees.

7. The package tray of claim 1, wherein the sidewalls of the grid comprise a closed cross sectional shape that comprises at least two line segments angled substantially 45 degrees from a plane formed by a largest planar surface of the base.

8. The package tray of claim 1, wherein the grid is integral with the base.

9. A package tray comprising:
a base comprising a largest planar surface comprising a grid of electromagnetic radiation reflectors coupled thereto;
wherein sidewalls of the grid of electromagnetic radiation reflectors are angled to a plane formed by the largest planar surface of the base.

10. The package tray of claim 9, wherein the sidewalls direct electromagnetic radiation toward sides of a plurality of semiconductor packages located within the grid.

11. The package tray of claim 9, wherein the electromagnetic radiation is ultraviolet light.

12. The package tray of claim 9, wherein the electromagnetic radiation is emitted by an electromagnetic radiation source oriented substantially directly above the largest planar surface of the base.

13. The package tray of claim 9, wherein the sidewalls of the grid comprise a triangular cross sectional shape.

14. A method of curing a plurality of semiconductor packages comprised in a package tray, the method comprising:
providing a base and a grid of electromagnetic radiation reflectors coupled to a largest planar side of the base;
placing a plurality of semiconductor packages into openings in the grid resting against the base;
directing electromagnetic radiation toward sides of each the plurality of semiconductor packages located within the grid using sidewalls of the grid of electromagnetic radiation reflectors; and
curing a component of the plurality of semiconductor packages using the electromagnetic radiation.

15. The method of claim 14, wherein the electromagnetic radiation is ultraviolet light.

16. The method of claim 14, further comprising emitting the electromagnetic radiation from an electromagnetic radiation source oriented substantially directly above a largest planar surface of the base.

17. The method of claim 14, wherein the sidewalls of the grid comprise a triangular cross sectional shape.

18. The method of claim 17, wherein angles of two vertices of the triangular cross sectional shape adjacent to the base are substantially 45 degrees.

19. The method of claim 17, where angles of two vertices of the triangular cross sectional shape adjacent to the base is between 45 degrees to 60 degrees.

20. The method of claim 14, wherein the sidewalls of the grid comprise a closed cross sectional shape that comprises at least two line segments angled substantially 45 degrees from a plane formed by a largest planar surface of the base.
